(19) United States
(12) Patent Application Publication
(10) Pub. No.: US 2014/0110163 A1
(43) Pub. Date: Apr. 24, 2014

(54) SUBSTRATE CASE STRUCTURE

(71) Applicant: Nozomi Etsumi, Saitama (JP)

(72) Inventor: Nozomi Etsumi, Saitama (JP)

(21) Appl. No.: 14/125,888

(22) PCT Filed: May 31, 2012
(86) PCT No.: PCT/JP2012/064140

§ 371 Date: Dec. 12, 2013

(30) Foreign Application Priority Data
Jun. 22, 2011 (JP) 2011-138282

(51) Int. Cl. B60R 16/02; H05K 7/14

(52) U.S. Cl. CPC B60R 16/02; H05K 7/1417
USPC 174/480

(57) ABSTRACT

A substrate case 4 includes an inner case 11 capable of housing an elongated substrate 3 thereinside; and an outer case 12 capable of housing the inner case 11. The inner case 11 has in one end portion an elongated substrate insertion opening 13 through which the elongated substrate 3 can be inserted; and the outer case 12 has in another end portion an inner case insertion opening 14 through which the inner case 11 can be inserted. A substrate clipping portion 15 capable of clipping the elongated substrate 3 is provided inside the inner case 11; and a substrate suppressing portion 16 capable of suppressing the elongated substrate 3 from clattering is provided inside the outer case 12. The outer case 12 includes an exterior fixing portion 18 that can be attached to a to-be-attached member 17.

### TECHNICAL FIELD

The present invention relates to a substrate case structure.

### BACKGROUND ART

An instrument panel is provided in a front portion of a vehicle interior of a vehicle such as an automobile. Inside of this instrument panel, a vehicle body reinforcement member is provided so as to extend in a vehicle width direction. And a wire harness is attached along the vehicle body reinforcement member.

The above vehicle body reinforcement member is also called as a steering support member or a cross car beam. In addition, the above wire harness is abundle of wires for supplying electric power, signals, or the like to each part of the vehicle body.

In recent years, along with a promotion of computerization and an increased number of electrical spectaculars in a vehicle, the wire harness has been being larger and heavier. Therefore, with the view to weight saving and high functionality, the wire harness is being replaced with an electronic substrate. This substrate (a so-called harness substrate) is elongated (an elongated substrate) along the vehicle body reinforcement member in a state where surfaces face an upward and a downward direction, respectively, and attached to the vehicle body reinforcement member in a state where the substrate is housed in a substrate case (see Patent Document 1, for example).

As for a conventional substrate case, an upper case and a lower case are attached on an upper surface and a lower surface of the elongated substrate, respectively, so as to sandwich the elongated substrate from an upward and a downward direction, and a fastening member such as a bolt and nut is used to fasten the upper case and the lower case in the upward and the downward direction.

### PRIOR ART DOCUMENT

### Patent Document

JP-A-2010-35256

### SUMMARY OF THE INVENTION

### Problems that the Invention is to Solve

However, there is a following problem in the conventional substrate case.

Namely, the substrate case is constructed to have the upper case and the lower case, which are dividable in the upward and the downward direction, so that the elongated substrate is sandwiched with the upper case and lower case from the upward and the downward direction. With this, attaching areas of the upper case and the lower case with respect to the elongated substrate become larger. Therefore, the number of positions for the fastening members becomes larger in order to attach the substrate case onto the elongated substrate in such a manner that the elongated substrate is suppressed from being distorted. In addition, strict dimensional control is required for a degree of warpage or the like of the substrates at the time of attaching the substrate case onto the elongated substrate.

### Means for Solving the Problems

In order to solve the above problem, a substrate case structure according to the present invention is characterized by comprising: an inner case capable of housing an elongated substrate thereinside; and an outer case capable of housing the inner case together with the elongated substrate, wherein the inner case has in one end portion an elongated substrate insertion opening through which the elongated substrate can be inserted in a direction in parallel with a surface of the elongated substrate, wherein the outer case has in another end portion an inner case insertion opening through which the inner case can be inserted in the direction in parallel with the surface of the elongated substrate, wherein a substrate clipping portion is provided inside the inner case, the substrate clipping portion being capable of clipping the elongated substrate in a direction perpendicular to the surface of the elongated substrate, wherein a substrate suppressing portion is provided inside the outer case, the substrate suppressing portion being capable of suppressing the elongated substrate from clattering in the direction perpendicular to the surface of the elongated substrate, and wherein the outer case includes an exterior fixing portion that can be attached to a to-be-attached member.

### BRIEF DESCRIPTION OF THE DRAWINGS

FIG. 1 is a perspective view entirely illustrating a state where a substrate case according to an example of the present invention is attached on a vehicle body reinforcement member.

FIG. 2 is an entire perspective view of the substrate case alone of FIG. 1.

FIG. 3 is an exploded perspective view of the substrate case of FIG. 1.

FIG. 4 is a perspective view of an inner case illustrated in FIG. 2.

FIG. 5 is a perspective view of an outer case illustrated in FIG. 2.

FIG. 6 is a cross-sectional view of the substrate case of FIG. 2.

FIG. 7 is a cross-sectional view of a position of a substrate clipping portion illustrated in FIG. 4.

FIG. 8 is a partially enlarged perspective view of a center position restricting portion of the outer case of FIG. 3.

FIG. 9 is a partially enlarged perspective view of a center position restricting portion of the inner case.

FIG. 10 is a cross-sectional view of a position of a longitudinal direction restricting portion illustrated in FIG. 4.

### MODES FOR CARRYING OUT THE INVENTION

In the following, an example into which the present invention is embodied is explained in detail with reference to the drawings.

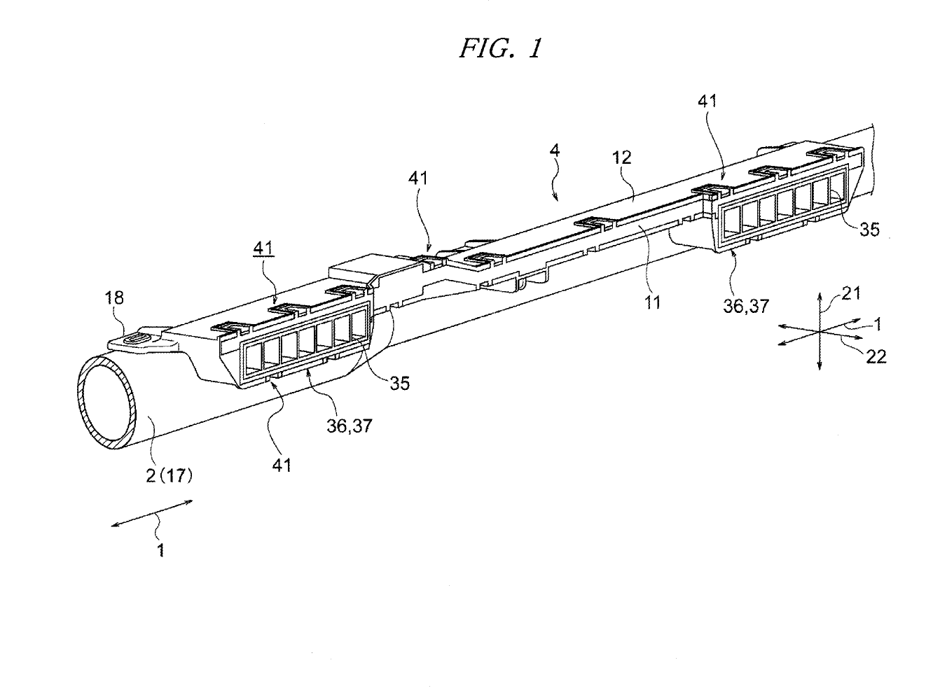

FIGS. 1 through 10 illustrate this example and its modified example.

### EXAMPLE

<Structure> A structure is explained in the following.

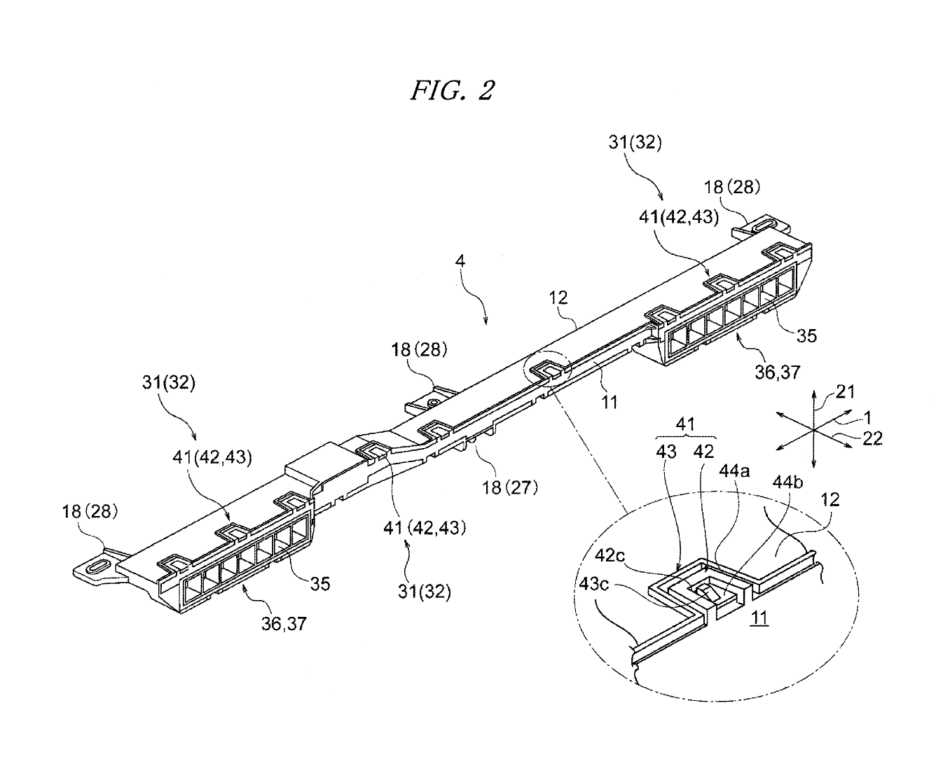

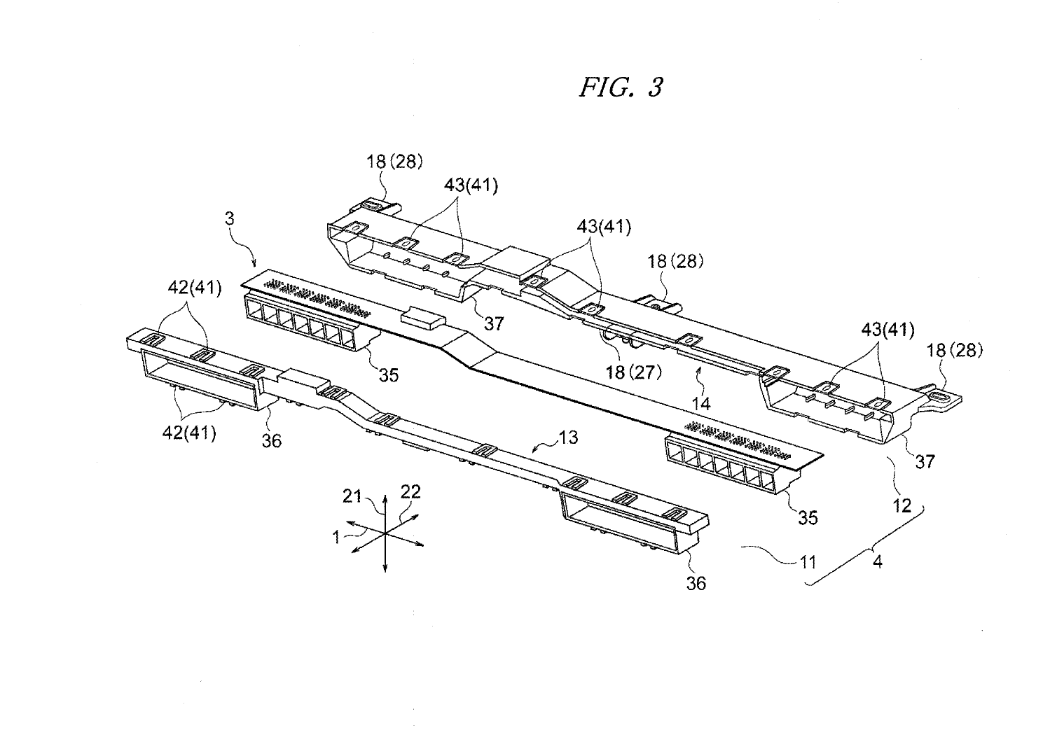

An instrument panel is provided in a front portion of a vehicle interior of a vehicle such as an automobile. Inside this instrument panel, a vehicle body reinforcement member 2 is provided so as to extend in a width direction 1 of the vehicle. And a harness substrate, which has been made by evolving a so-called wire harness into a substrate form, is arranged along the vehicle body reinforcement member 2. This harness substrate is composed of an elongated substrate 3 (see FIG. 3) having a length (for example, about 2 m) close to a width dimension of the vehicle, as understood from an assembly drawing of FIG. 2 and an exploded perspective view of FIG. 3. Alternatively, the harness substrate is composed by linking two elongated substrates 3 having a length (for example, about 1 m) close to about half of the vehicle width, although not illustrated. The elongated substrate 3 is housed in a substrate case 4, and fixed on an upper portion of the vehicle body reinforcement member 2 while being housed in the substrate case 4. Incidentally, depending on a structure of a vehicle, the substrate case 4 with the elongated substrate 3 housed therein may be fixed in a lower portion, a front portion, or a rear portion of the vehicle body reinforcement member 2.

The above vehicle body reinforcement member 2 is called as a steering support member or a cross car beam. In addition, the above wire harness is a bundle of wires for supplying electric power, signals, or the like to each part of the vehicle body. The harness wire is the elongated substrate 3 made by evolving a so-called wire harness into a substrate form, as described above. The elongated substrate 3 is extremely difficult to produce and greatly subject to distortion or warpage, compared to a square substrate, which is relatively short and small such as a normal substrate.

With respect to the above basic structure, vehicle according to this example has the following structure.

Incidentally, the following explanation is made for a case where the elongated substrate 3 is the above-mentioned harness substrate. However, such an elongated substrate 3 is not limited to the harness substrate.

And this harness substrate is the elongated substrate 3 that has a narrow width in relation to a front and a rear direction 22 of the vehicle and extends in the width direction 1 of the vehicle, while surfaces (mounting surfaces) face substantially an upward and a downward direction 21, respectively. With this, in the elongated substrate 3, side portions (a front end portion and a rear end portion) positioned in relation to the front and the rear direction 22 of the vehicle are long sides; and end portions (a right end portion and a left end portion) positioned in relation to the width direction 1 of the vehicle.

Incidentally, the harness substrate may be an elongated substrate 3 that has a narrow width in relation to the upward and the downward direction 21 of the vehicle and extends in the width direction 1 of the vehicle, while surfaces (mounting surfaces) face substantially the front and the rear direction 22 of the vehicle, respectively. As for this case, the following explanations are applicable, when read with the upward and the downward direction 21 replaced with the front and the rear direction 22 of the vehicle, although explanations are not particularly made.

The substrate case 4 of this example is provided with an inner case 11 that is capable of housing the elongated substrate 3 therein, and an outer case that is capable of housing the inner case 11 along with the elongated substrate 3 therein.

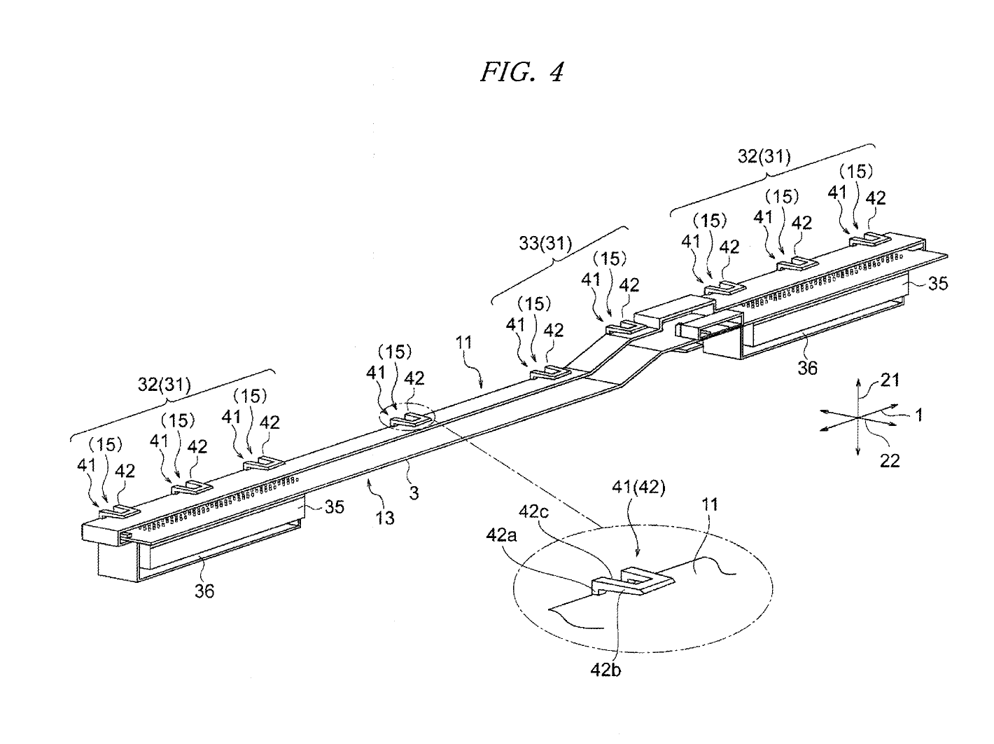

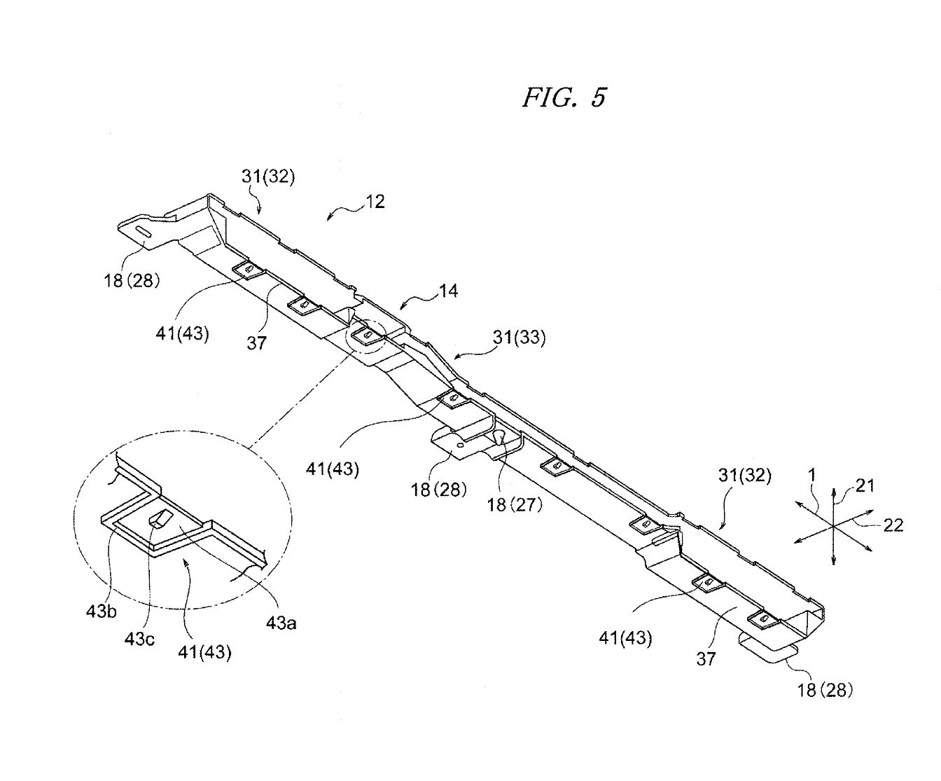

As illustrated in FIG. 4, the inner case 11 has an elongated substrate insertion opening 13 in one side portion, which allows the elongated substrate 3 to be inserted therethrough in a direction in parallel with the surfaces of the elongated substrate 3. In addition, as illustrated in FIG. 5, the outer case 12 has an inner case insertion opening 14 in the other side portion, which allows the inner case 11 to be inserted therethrough in the direction in parallel with the surfaces of the elongated substrate 3.

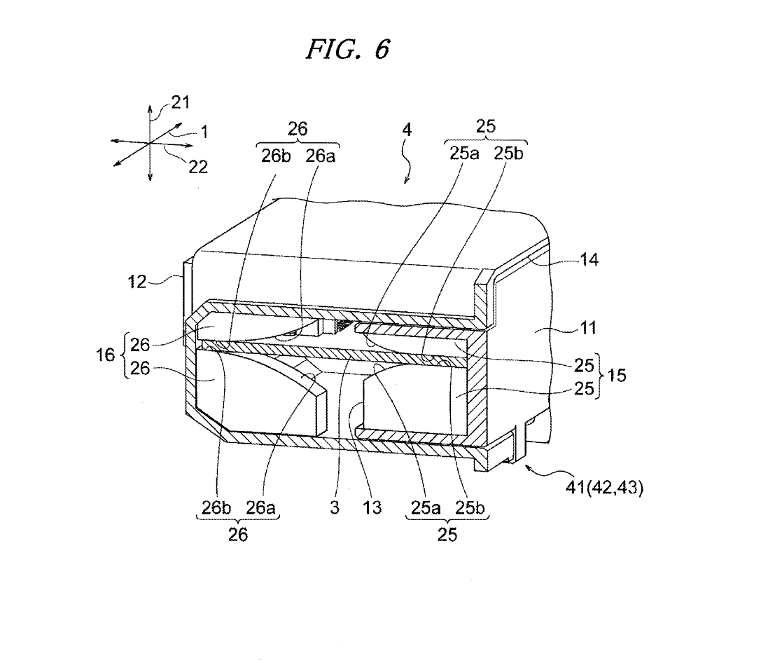

Moreover, as illustrated in the cross-sectional view of FIG. 6, a substrate clipping portion 15 that is capable of clipping and holding the elongated substrate 3 from a direction perpendicular to the surfaces of the elongated substrate 3 is provided inside the inner case 11. In addition, a substrate suppressing portion 16 that suppresses the elongated substrate 3 from clattering in the direction perpendicular to the surfaces of the elongated substrate 3 is provided inside the outer case 12.

And as illustrated in FIG. 2, the outer case 12 has exterior fixing portions 18 that can be fixed to a to-be-attached member 17. The to-be-attached member 17 is explained later.

In the following, supplemental explanations are made about the fore going explanation. However, the following supplemental explanations are simply exemplified, but not limiting (the same applies hereinafter).

The above “one side portion” is the front end portion (a front face portion) or the rear end portion (a rear face portion) in the front and the rear direction 22 of the vehicle; and the above “other side portion” is the rear end portion (the rear face portion) or the front end portion (the front face portion) in the front and the rear direction 22 of the vehicle. In addition, the above “direction in parallel with the surfaces of the elongated substrate 3” is along the front and the rear direction 22 of the vehicle. The above “direction perpendicular to the surfaces of the elongated substrate 3” is along the upward and the downward direction 21. Incidentally, the direction in parallel with the surfaces of the elongated substrate 3″ includes the width direction 1 of the vehicle and an intermediate (or inclined) direction between the front and the rear direction 22 of the vehicle and the width direction 1 of the vehicle. However, in a case of these directions an amount of insertion becomes larger, or a structure becomes complicated, so that the elongated substrate 3 and the inner case 11 are preferably inserted in a direction along the front and the rear direction 22.

And the above “inner case 11” is a member that extends slightly longer than the elongated substrate 3 in the width direction 1 of the vehicle, has an opening serving as the elongated substrate insertion opening 13 in one side portion; and has a substantially C-shaped cross section, in side view, which has a substrate housing space therein. Transverse arm portions (forming a vertical pair) of the inner case 11, which have the C-shaped cross section, have about a half of the width dimension of the elongated substrate 3. With this, a half of the elongated substrate 3 is housed in the inner case 11. The inner case 11 may be provided at both end portions with end surface portions that cover at least part of the C-shaped cross section.

In addition, the “outer case 12” is a member that extends slightly longer than the inner case 11 in the width direction 1 of the vehicle, has an opening serving as the inner case insertion opening 14 in the other side portion, and has, a substantially C-shaped cross section, in side view, which has the substrate housing space or an inner case housing space therein. The inner case insertion opening 14 of the outer case 12 is provided so as to oppose the elongated substrate insertion opening 13 of the inner case 11. Transverse arm portions (forming a vertical pair) of the outer case 12, which have the C-shaped cross section, have about the entire width dimension of the inner case 11. The outer case 12 may be provided at both end portions with end surface portions that cover at least part of the C-shaped cross section.

The above “elongated substrate insertion opening 13” extends in a longitudinal direction (or the width direction 1 of the vehicle, the same applies hereinafter) of the elongated substrate 3. The elongated substrate insertion opening 13 has a gap in the upward and the downward direction 21, the gap being equal to or slightly larger than a thickness of the elongated substrate 3, so that the elongated substrate 3 can be inserted therethrough. In this case, because the substrate clipping portion 15 is provided inside the inner case 11, the elongated substrate insertion opening 13 has the gap in the upward and the downward direction 21, which is as large as a summation of the thickness of the elongated substrate 3 and a dimension of the substrate clipping portion 15 in a height direction.

In addition, the “inner case insertion opening 14” extends in the longitudinal direction of the elongated substrate 3. The inner case insertion opening 14 has a gap (in the upward and the downward direction 21), which is equal to or slightly larger than a thickness of the inner case 11. This gap allows the inner case 11 to be housed with substantially no clearance.

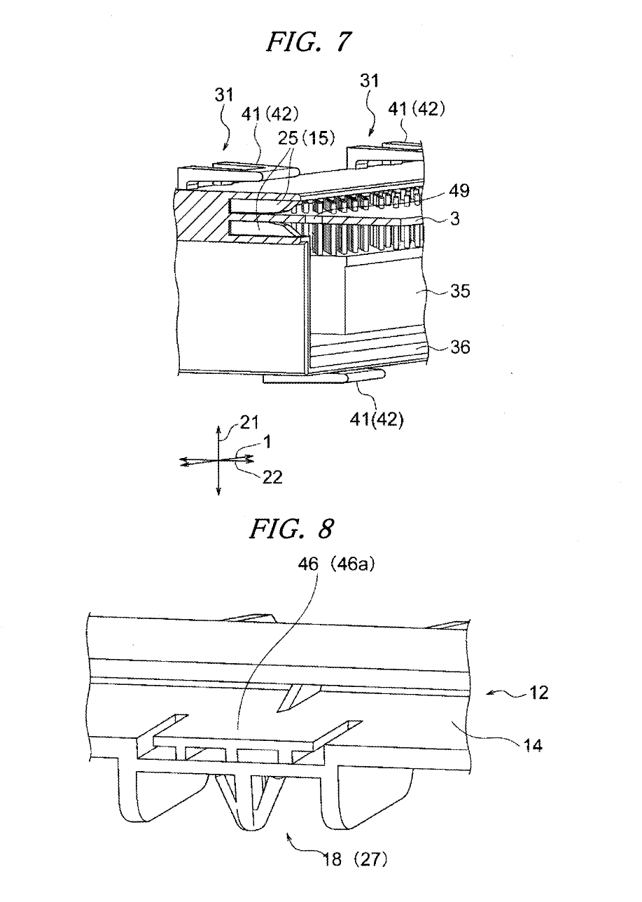

The above “substrate clipping portion 15” is configured of, for example, a (vertical) pair of press fitting ribs 25 provided in an inner portion of the C-shaped cross section of the inner case 11, as illustrated in the cross-sectional views of FIG. 6 and FIG. 7. Inclined portions 25a, which come closer to each other toward the back, are provided at least at inlet side portions of portions, which clip the surfaces of the elongated substrate 3, in the pair of the press fitting ribs 25. These inclined portions 25a may be in a form of a straight line or a (convexly) curved line. In addition, parallel portions 25b having a gap that is equal to or slightly smaller than the thickness of the elongated substrate 3 are provided at back portions in the press fitting ribs 25, when needed. A plurality of the substrate clipping portions 15 are provided along a longitudinal direction of the inner case 11.

In addition, the “substrate suppressing portion 16” is configured of, for example, a (vertical) pair of suppressing ribs 26 provided in the inner portion of the C-shaped cross section of the outer case 1, as illustrated in FIG. 6. Inclined portions 26a, which come closer to each other toward the back, are provided at least at inlet side portions of portions, which suppress the surfaces of the elongated substrate 3 from clattering, in the pair of the suppressing ribs 26. These inclined portions 26a may be in a form of a straight line or a (convexly) curved line. In addition, parallel portions 26b having a gap that is slightly larger than that of the above-mentioned parallel portions 25b are provided at back portions in the suppressing ribs 26, when needed. A plurality of the substrate suppressing portions 16 are provided along a longitudinal direction of the outer case 12.

The above “to-be-attached portion 17” is, for example, the above-mentioned vehicle reinforcement member 2. The substrate case 4 is attached and fixed on the upper portion or the lower portion (the upper portion, in this case) of the vehicle reinforcement member 2. In addition, the “exterior fixing portions 18” can be configured of a pin fixing portion 27, thread fixing portions 28, or the like, as illustrated in FIG. 3 and a partially enlarged view of FIG. 8. In this case, the pin fixing portion 27 for positioning is provided at a center portion in the longitudinal direction of the outer case 12. This pin fixing portion 27 is configured of a locking pin for positioning that extends toward the vehicle reinforcement member 2 from a surface (a lower surface) that contacts the reinforcement member 2 of the outer case 12 substantially in the direction perpendicular to the surfaces. In contrast, in a corresponding position in the vehicle reinforcement member 2 (a center portion in the longitudinal direction), a pin hole (not illustrated) to which the locking pin for positioning is fit and locked is provided. In addition, the thread fixing portions 28 for fixing are provided in the center portion and both end portions (in three positions) along the longitudinal direction of the outer case 12. These thread fixing portions 28 are configured of attaching pieces that are formed to be outwardly bulged from the one side portion of the outer case 12 and have surfaces in parallel with the elongated substrate 3. Thread-hole portions for threading are provided in the corresponding attaching pieces. Among these thread-hole portions, the thread-hole portion at the center is a round hole for position-fixing, and the thread-hole portions at both end portions are long holes that extend in the longitudinal direction in order to absorb accidental errors and thermal expansion.

The above substrate clipping portions 15 may be provided in arbitrary positions, preferably in the following position.

The substrate clipping portions 15 are provided in corresponding distortion suppression points 31 of the elongated substrate 3, as illustrated in FIG. 4 and FIG. 7.

One or plural of the substrate clipping portion(s) 15 may be provided in each one of the distortion suppression points 31.

The distortion suppression points 31 reside in positions of a shape changing portion 33 or connector attachment portions 32 of the elongated substrate 3.

The “connector attachment portions 32” are portions in which corresponding outside connectors are attached to the elongated substrate 3, in literal terms. In this case, connectors 35, which enable connection of the outside connectors, are provided on the lower surface side of the both end portions in the elongated substrate 3. However, the connector attachment portions 32 are not necessarily provided in the above positions, but may be provide in appropriate positions.

In contrast, the inner case 11 and the outer case 12 are provided with connector housing portions 36, 37 that are capable of housing the connectors 35. The connector housing portions 36, 37 have opening portions that allow the outside connectors to be connected thereto. The opening portions are provided so as to face a rear side of the vehicle.

The “shape changing portion 33” is a portion where a shape of the elongated substrate 3 is changing, in literal terms. The elongated substrate 3 has an upper and a lower step portion serving as the shape changing portion 33 between the center portion and the end portions. The shape changing portion 33 may be formed in accordance with a shape changing portion of the upper surface of the to-be-attached member 17.

Moreover, a portion having a long mutual distance (a so-called long span portion) may be set as the distortion suppression point 31, and the substrate clipping portion 15 is provided in the portions. Incidentally, the substrate clipping portion 15 may be provided in other positions rather than these positions.

Incidentally, the substrate suppressing portion 16 is preferably provided in the same position as a position where the substrate clipping portion 15 is provided. For example, the substrate suppressing portion 16 may be provided so as to oppose the substrate clipping portion 15.

As illustrated mainly in FIG. 2, case fixing portions 41, which are capable of fixing the inner case 11 and the outer case 12 in the distortion suppression points 31, are provided in the inner case 11 and the outer case 12.

The “case fixing portions 41” suppress a movement of the inner case 11 in the direction perpendicular to the surfaces of the elongated substrate (the upward and a downward direction 21), and allow slight movement of the inner case 11 at least in the longitudinal direction (the width direction 1 of the vehicle).

The above case fixing portions 41 are engaging portions, each of which is composed of an engaging piece 42 provided in one of the inner case 11 and the outer case 12, and a to-be-engaged portion 43 provided in the other one of the inner case 11 and the outer case 12. The engaging piece 42 and the to-be-engaged portion 43 engage with each other, in literal terms, thereby to fix the inner case 11 and the outer case 12 together. In this case, the engaging portion 41 is provided in the inner case 11, and the to-be-engaged portion 43 is provided in the outer case 12. However, these configurations may be opposite.

As illustrated in FIG. 4, the above “engaging pieces 42” are provided so as to protrude toward an upper surface side or a lower surface side from the other end portion of the inner case 11. Each of the engaging pieces has a standing portion 42a that stands upward substantially in a direction in parallel with the upward and the downward direction 21 and has a length substantially equal to a height of the inner case insertion opening 14 of the outer case 12, and a parallel portion 42b that is bent from an end portion of the standing portion 42a so as to be in parallel with the upper surface of the outer case 12. The parallel portion 42b is capable of planarly contacting or pressure contacting the upper surface or the lower surface of the outer case 12. The parallel portion 42b may have a shape of, for example, a trapezoid that is tapered in planar view so as to be guided when being engaged to the to-be-engaged portion 43.

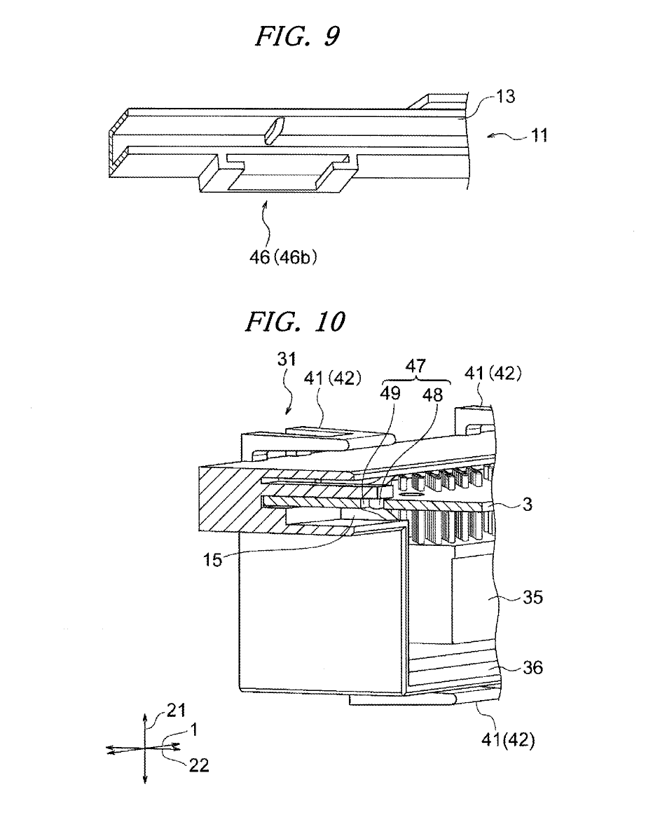

On the other hand, as illustrated in FIG. 5, each of the “to-be-engaged portions 43” is composed of a concave portion 43a that is provided in the upper surface or the lower surface of the other side portion of the outer case 12 and has a shape substantially matching the engaging piece 42, or a peripheral wall portion 43b that surrounds at least part of a periphery of the engaging piece 42, or the like. The concave portion 43a or the peripheral wall portion 43b has a shape of, for example, a trapezoid that is tapered in planar view so as to substantially match the engaging piece 42. Moreover, an inner click portion 43c may be provided inside the to-be-engaged portion 43, as illustrated in FIG. 5, and an inner click receiving portion 42c, which is in a form of a hole, may be provided inside the parallel portion 42b of the above engaging piece 42, which leads to double clicks, when needed. And as illustrated in FIG. 2, allowance gaps 44a, 44b are provided between the engaging piece 42 and the to-be-engaged portion 43 and between the inner click portion 43c and inner click receiving portion 42c, respectively, in order to have the case fixing portion 41 restrain the inner case 11 from moving along a direction perpendicular to the surfaces of the inner case 11 and allow the inner case 11 to slightly move along the longitudinal direction of the inner case 11 (the width direction 1 of the vehicle) in relation to the outer case 12, as described above. Incidentally, the allowance gaps 44a, 44b may be provided in relation to the front and the rear direction 22, in order to allow slight movement along the front and the rear direction 22. In addition, a center position defining portion 46, which is capable of defining a position of the center portion in the longitudinal direction, is provided in the inner case 11 and the outer case 12. This “center position defining portion 46” is provided with a slide guide 46a provided on the upper surface side of an interior of the outer case 12, as illustrated in FIG. 8, and a guide receiver 46b provided on the lower surface side of an exterior of the inner case 11, as illustrated in FIG. 9. The slide guide 46a and the guide receiver 46b extend in the insertion direction of the inner case 11 in relation to the outer case 12, and can be slidably engaged with each other. Shapes of the slide guide 46a and the guide receiver 46b are not limited to illustrated ones in the drawings. As illustrated in the cross-sectional view of FIG. 10, a longitudinal direction position restraining portion 47, which is capable of restraining a position of the elongated substrate 3 in the longitudinal direction, is provided in the inner case 11 and the elongated substrate 3.

This “longitudinal direction position restraining portion 47” is composed of a pair of click portions 48 for positioning in the longitudinal direction, which are provided on the both end portions or their vicinities of an interior of the inner case 11, a pair of click receiving portions 49 for positioning in the longitudinal direction, which are provided on the both end portions or their vicinities of the elongated substrate 3, or the like.

The above “click portions 48 for positioning in the longitudinal direction” extend from a vertical linking portion of a C-shaped cross section of the inner case 11 so as to be in parallel with the transverse arm portion. These click portions 48 for positioning in the longitudinal direction are locked with the elongated substrate 3 from the upper surface side.

In addition, regarding the “click receiving portions 49 for positioning in the longitudinal direction”, one is, for example, a round hole, and the other is, for example, a long hole that extends in the longitudinal direction or a notch portion in a form of a long hole, in order to absorb accidental errors and thermal expansion. The round hole and the long hole are provided in the center portion or the like of the width of the elongated substrate 3.

Incidentally, a structure of the substrate case 4 described above is widely applicable to an elongated substrate 3 which is not the harness substrate.

<Operation> Operation of this example is explained in the following.

The elongated substrate 3 is inserted into the outer case 12, in a state where the elongated substrate 3 has been inserted in the inner case 11.

Specifically, the elongated substrate 3 is inserted into the one side portion of the elongated substrate insertion opening 13 of the inner case 11 from the other side portion side, being kept in parallel with the surfaces of the elongated substrate 3. In addition, the inner case 11 that houses the elongated substrate 3 is inserted into the other side portion of the inner case insertion opening 14 of the outer case 12 from the one side portion side, being kept in parallel with the surfaces of the elongated substrate 3.

The elongated substrate 3 housed in the inner case 11 is clipped (or press-fitted) and thus held by the substrate clipping portion 15 provided inside the inner case 11 from the directions perpendicular to the surfaces of the elongated substrate 3. In addition, the elongated substrate 3 that has been housed in the outer case 12 together with the inner case 11 is suppressed so as not to clatter by the substrate suppressing portion 16 provided inside the outer case 12. In such a manner, by providing the substrate suppressing portion 16 inside the outer case 12, it makes it difficult to propagate influences from outside such as vibrations to the elongated substrate 3, while the elongated substrate 3 is held.

And the outer case 12 is fixed by the exterior fixing portion 18 attached to the to-be-attached member 17.

<Effects> According to this example, the following effects can be obtained.

The substrate case 4 is structured so as to be dividable toward the sides of the one side portion and the other side portion (the front and the rear direction 22 of the vehicle, in the above example), rather than the upward and the downward direction 21, and to constrain the elongated substrate 3 in the direction perpendicular to the surfaces of the elongated substrate 3 by the substrate clipping portions 15 and the substrate suppressing portions 16. Because of this, distortion of the elongated substrate 3 can be effectively suppressed only by attaching the substrate case 4 to the elongated substrate 3. Therefore, it is unnecessary to use a large number of fastening members, and thus to control a warpage amount in the elongated substrate 3 due to a fastening amount or the like of the fastening members at the time of assembling. With this, part costs and the number of attaching processes can be greatly reduced.

In addition, by setting the substrate clipping portions 15 in the distortion suppression points 31 of the elongated substrate 3, the distortion of the elongated substrate 3 can be effectively suppressed by the substrate clipping portions 15.

In addition, by setting the shape changing portion 33 or the connector attachment portions 32 of the elongated substrate 3 as the distortion suppression point(s) 31, a majority of positions in the elongated substrate 3, which tend to be distorted, can be complemented thereby to efficiently suppress the distortion.

The inner case 11 and the outer case 12 are engaged and fixed with each other by the case fixing portions 41. And, by setting the case fixing portions 41 in the distortion suppression points 31, the elongated substrate 3 can be further effectively suppressed.

Moreover, the engaging pieces 42 are provided in one of the inner case 11 and the outer case 12; and the to-be-engaged portions 43 are provided in the other one of the inner case 11 and the outer case 12. Therefore, the inner case 11 and the outer case 12 can be simply and surely engaged with each other, at one touch by inserting the inner case 11 into the outer case 12.

In addition, the position of the elongated substrate 3 in the longitudinal direction in relation to the inner case 11 can be surely restrained by the longitudinal direction position restraining portion 47 provided in the inner case and the elongated substrate 3.

In the foregoing, an example of this invention has been described in detail with reference to drawings. However, the example is merely an exemplary illustration of this invention. Therefore, this invention is not limited solely to the configuration in the example, and naturally includes changes of design and the like that are made without departing from the scope of this invention. Moreover, when an example includes, for example, plural configurations, this invention naturally includes feasible combinations of these configurations even without specific descriptions thereof. Further, when plural examples and/or plural modifications are given, this invention naturally includes feasible combinations of configurations ranging over these even without specific descriptions thereof. Also, this invention naturally includes the configurations depicted in the drawings even without specific descriptions thereof. Furthermore, when there is the wording “and/or the like,” this wording is used to mean that equivalents are included. Additionally, when there are the wordings “substantially”, “about”, “around” or the like, these wordings are used to mean that commonsensically admitted ranges or accuracies are included.

Incidentally, this application is based on a Japanese Patent Application (No. 2011-138282) filed on Jun. 22, 2011, the entire contents of which are herein incorporated by reference. In addition, all the references referred to here are entirely taken herein.

### DESCRIPTION OF REFERENCE NUMERALS

3 elongated substrate
4 substrate case
11 inner case
12 outer case
13 elongated substrate insertion opening
14 inner case insertion opening
15 substrate clipping portion
16 substrate suppressing portion
17 to-be-attached member
18 exterior fixing portion
31 distortion suppression point
32 connector attachment portion
33 shape changing portion
41 case fixing portion
42 engaging piece
43 to-be-engaged portion

1. A substrate case structure characterized by comprising:
an inner case capable of housing an elongated substrate thereinside; and
an outer case capable of housing the inner case together with the elongated substrate, wherein:
the inner case has in one end portion an elongated substrate insertion opening through which the elongated substrate can be inserted in a direction in parallel with a surface of the elongated substrate;
the outer case has in another end portion an inner case insertion opening through which the inner case can be inserted in the direction in parallel with the surface of the elongated substrate;
a substrate clipping portion is provided inside the inner case, the substrate clipping portion being capable of clipping the elongated substrate in a direction perpendicular to the surface of the elongated substrate;
a substrate suppressing portion is provided inside the outer case, the substrate suppressing portion being capable of suppressing the elongated substrate from clattering in the direction perpendicular to the surface of the elongated substrate; and
the outer case includes an exterior fixing portion that can be attached to a to-be-attached member.

2. The substrate case structure recited in claim 1, wherein
the substrate clipping portion is provided in a distortion suppression point of the elongated substrate.

3. The substrate case structure recited in claim 2, wherein
the distortion suppression point resides in one of a shape changing portion and a connector attachment portion of the elongated substrate.

4. The substrate case structure recited in claim 2, wherein
a case fixing portion is provided in the inner case and the outer case, the case fixing portion being capable of fixing the inner case and the outer case in the distortion suppression point.

5. The substrate case structure recited in claim 4, wherein
the case fixing portion includes an engaging piece provided in one of the inner case and the outer case, and a to-be-engaged portion provided in the other one of the inner case and the outer case.
